(19) United States
(12) Patent Application Publication
(10) Pub. No.: US 2011/0012082 A1
(43) Pub. Date: Jan. 20, 2011

(54) ELECTRONIC COMPONENT COMPRISING A CONVERTIBLE STRUCTURE

(75) Inventor: David Tio Castro, Herverlee (BE)

Correspondence Address: NXP, B.V.;NXP INTELLECTUAL PROPERTY & LICENSING, M/S41-SJ, 1109 MCKAY DRIVE, SAN JOSE, CA, 95131, US

(73) Assignee: NXP B.V., Eindhoven (NL)

(21) Appl. No.: 12/933,590

(22) PCT Filed: Mar. 18, 2009
(86) PCT No.: PCT/IB09/51143

§ 371 Date: Sep. 20, 2010

(30) Foreign Application Priority Data
Mar. 21, 2008 (EP) 08102848.2
Mar. 18, 2009 (IB) PCT/IB2009/051143

(51) Int. Cl. H01L 45/00; H01L 21/02

(52) U.S. Cl. 257/2; 438/54; 257/E45.002; 257/E21.003

(57) ABSTRACT

An electronic component (100, 1400) comprises a first electrode (106), a second electrode (107), a convertible structure (102) electrically coupled between the first electrode (106) and the second electrode (107), being convertible between at least two states by heating and having different electrical properties in different ones of the at least two states, and a retention enhancement structure (108, 1402) arranged between the first electrode (106) and the second electrode (107), connected to the convertible structure (102) and configured for suppressing conversion between different ones of the at least two states in the absence of heating.

### FIELD OF THE INVENTION

The invention relates to an electronic component.

Moreover, the invention relates to a method of manufacturing an electronic component.

### BACKGROUND OF THE INVENTION

In the field of non-volatile memories, flash memory scaling beyond a 45 nm node has become a real issue. Technologies to face this challenge are ferroelectric, magnetic and phase change memories, the latter one being promising for the replacement of flash and showing characteristic that may allow replacement of other types of memories such as DRAM. Phase change memories are a possible solution for the unified memory being an important step in the electronics art. OTP (“on time programmable”) and MTP (“multiple times programmable”) memories open a field that may present a great opportunity for phase change memories as well.

Phase change materials may be used for storing information. The operational principle of these materials is a change of phase. In a crystalline phase, the material structure is, and thus properties are, different from the properties in the amorphous phase.

The programming of a phase change material is based on the difference between the resistivity of the material in its amorphous and crystalline phase. To switch between both phases, an increase of the temperature is required. Very high temperatures with rapid cooling down will result in an amorphous phase, whereas a smaller increase in temperature or slower cooling down leads to a crystalline phase. Sensing the different resistances may be done with a small current that does not cause substantial heating.

The increase in temperature may be obtained by applying a pulse to the memory cell. A high current density caused by the pulse may lead to a local temperature increase. Depending on the duration and amplitude of the pulse, the resulting phase will be different. Larger pulse amplitudes, so-called RESET pulses, may amorphize the cells, whereas smaller pulse amplitudes will SET the cell to its crystalline state, these pulses are also called SET pulses.

The chalcogenide phase-change materials are divided in two classes with slightly different compositions, based on their crystallization mechanism. The “nucleation dominated” materials along the GeTe—Sb₂Te₃ tie line such as Ge₂Sb₂Te₅ are generally used in Ovonic Unified Memory (OUM) devices. In this concept, the PC material is in contact with a bottom resistive electrode to switch reversibly a small volume of PC material. The crystallization dynamics of these materials rely in the formation and growth of crystalline nuclei in the core of an amorphous region.

“Fast growth” materials, known in optical storage application (CD-RW/DVD+RW), enable very fast switching (10 ns) with improved phase stability. They are used in a line cell concept. In this approach, the active part of the memory device is a Phase change line formed in-between two electrodes formed in the Back End Of Line Process (BEOL) of a CMOS based front end of line. In these materials the crystallization dynamics are based in the movement of the crystalline-amorphous interface and in the recoiling of the amorphous zone. The nucleation is marginal.

U.S. Pat. No. 4,433,342 discloses that a residual crystallization retardation layer is provided between the non-crystalline switchable semiconductor layer and each electrode structure. Amorphous germanium, silicon or carbon form good crystallization retardation layers and also minimize electromigration and reduce solubility of tellurium in the electrodes.

EP 0,201,860 discloses a multilayered article, which includes at least one periodically repeating set including a layer of amorphous crystallizable material and a layer of crystallization inhibiting material in generally superposed relationship. The layer of crystallizable material has its crystallization temperature raised by the presence of the inhibiting layer.

However, the retention time of conventional memory cells may be comparable very short.

### OBJECT AND SUMMARY OF THE INVENTION

It is an object of the invention to provide an electronic component having a convertible structure, which has a sufficiently long retention time.

In order to achieve the object defined above, an electronic component and a method of manufacturing an electronic component according to the independent claims are provided.

According to an exemplary embodiment of the invention, an electronic component (such as a memory cell) is provided comprising a first electrode (such as a first metallic structure) and a second electrode (such as a second metallic structure), a convertible structure (such as a phase change material, particularly in a basically planar configuration) electrically coupled between the first electrode and the second electrode (for instance directly connected thereto), being convertible between at least two states by heating and having different electrical properties in different ones of the at least two states, and a retention enhancement structure arranged between the first electrode and the second electrode, connected to the convertible structure and configured for suppressing conversion (for instance for retarding, delaying and/or preventing conversion) between different ones of the at least two states in the absence of heating (for example a barrier (for instance embedded as one or multiple pieces) within the convertible structure configured for suppressing conversion between different ones of the at least two states in the absence of heating (that is particularly preventing an undesired conversion from one state into another one even when no converting signal in form of a heating pulse is applied externally); additionally or alternatively, one of the retention enhancement structure and the convertible structure may comprises a material section being altered as compared to the other one of the retention enhancement structure and the convertible structure (for instance one of the retention enhancement structure and the convertible structure may be formed based on a material of the other one of the retention enhancement structure and the convertible structure by chemical and/or physical conversion) for suppressing conversion between different ones of the at least two states in the absence of heating).

According to another exemplary embodiment of the invention, a method of manufacturing an electronic component is provided, the method comprising electrically coupling a convertible structure between a first electrode and a second electrode, the convertible structure being convertible between at least two states by heating and having different electrical properties in different ones of the at least two states, and forming a retention enhancement structure between the first electrode and the second electrode, connected to the convertible structure and configured for suppressing conversion between different ones of the at least two states in the absence of heating (for instance forming a barrier within the convertible structure configured for suppressing conversion between different ones of the at least two states in the absence of heating; additionally or alternatively, the forming may comprise altering a material section of the convertible structure into the retention enhancement structure for suppressing conversion between different ones of the at least two states in the absence of heating).

The term “retention enhancement structure” may particularly denote a physical structure which is specifically configured for at least partially spatially delimiting the convertible structure and by providing an at least partial boundary of the convertible structure along a conductive path between two electrodes in such a manner that the spontaneous, i.e. not intentionally triggered by applying an electric programming signal, formation and spatial movement of a wall separating different phases of the convertible structure is inhibited or prevented or delayed or retarded or reduced or decreased or attenuated.

The term “in the absence of heating” may particularly denote “in the absence of external heating for phase conversion purposes”, for instance in the absence of sufficiently intense electric or ohmic heating (as achieved by a set or reset pulse) with the intention to convert the convertible structure between two phases. However, in the presence of only very weak heating, the retention enhancement structure should render unintentional phase conversion unlikely or even impossible. Of course, there can be always minor heating from an environment, etc., and (re-)crystallization should be prevented even under such conditions. Hence, in the absence of intentional or deliberate or aimed or targeted heating or in the presence of mere undesired heating or heat, undesired phase conversion should be inhibited due to a corresponding configuration of the retention enhancement structure.

The term “barrier” may particularly denote a layer or any other physical structure which is shaped, arranged and dimensioned to be embedded in and to traverse the convertible structure partially or entirely to thereby provide for an efficient inhibitor suppressing or preventing undesired phase change of the convertible structure, particularly undesired recrystallization of a phase change material (more particularly of a phase change material of the fast growth type) without applying an external recrystallization signal.

The term “electronic component” may particularly denote any component, member or apparatus, which fulfils any electric, magnetic and/or electronic functionality. This means that electric, magnetic and/or electromagnetic signals may be applied to and/or generated by the electronic component during regular use.

The term “modified material section” may particularly denote that material of one of the retention enhancement structure and the convertible structure is generated based on a material of the respective other one of these two components by undergoing a dedicated treatment such as an ion implantation or a chemical reaction. In such an embodiment, material of one of the retention enhancement structure and the convertible structure is convertible into the other one of the retention enhancement structure and the convertible structure.

The term “convertible structure” may particularly denote any physical structure having convertible properties. Examples are a phase change structure or a structure with thermo-dependent properties. Phase change materials can have not only two phases but also more than two phases, for instance crystalline, amorphous, meta-amorphous, meta-crystalline, crystalline with a different lattice orientation, etc.

A “phase change by heating” may particularly denote any change of any physical parameter or material property under the influence of heat (generated by ohmic losses of an electric current flowing through the phase change structure or an electrically/a thermally coupled heating element, and/or generated by the absorption of electromagnetic radiation).

The term “memory cell” may particularly denote a physical structure (such as a layer sequence, for instance monolithically integrated on/in a substrate such as a silicon substrate) which allows to store information in an electronic manner. An amount of information stored in a memory cell may be one (1) bit (particularly when the phase change material is switched between two phases representing logical values “1” or “0”) or may be more than 1 bit (particularly when the phase change material is switched between at least three phases). The memory cell may be formed on and/or in a substrate, which may denote any suitable material, such as a semiconductor, glass, plastic, etc.

The term “substrate” may be used to define generally the elements for layers that underlie and/or overlie a layer or portions of interest. Also, the substrate may be any other base on which a layer is formed, for example a semiconductor wafer such as a silicon wafer or silicon chip.

According to an exemplary embodiment of the invention, a retention enhancement structure is directly spatially connected to a convertible structure so as to selectively prevent any crystalline-amorphous interfaces which may conventionally act as a seed or a starting point for a spontaneous undesired phase transition. By inhibiting such a spontaneous phase change which is not initiated externally, the durability of the phase state of the convertible structure may be significantly increased, thereby improving retention time. Additionally, such a retention enhancement structure may increase the effective length of a line of the convertible structure which may have an advantageous impact on the threshold voltage of such a structure which thereby can be efficiently reduced. This can be combined with a further advantageous effect of a reduced power requirement for switching such an artificially extended convertible structure.

According to an exemplary embodiment of the invention, a barrier structure (which may be a continuous or a non-continuous physical structure) may be embedded or integrated within a convertible structure so as to form one or more islands of the convertible structure each of the islands being configured in such a manner that upon programming the electronic component, the island of convertible material is entirely brought to a specific state. Undesired loss of a previously adjusted state (such as a recrystallization in a fast growth phase change material) may be securely prevented by the barrier walls within the convertible structure by providing a mechanical resistance preventing such an undesired loss of information. Therefore, electronic components having a switching state defined by an external signal may be maintained in such a state for a long time, for instance allowing manufacturing memory cells having a longer retention time.

According to an exemplary embodiment of the invention, a barred phase change cell may be provided to improve data retention particularly of fast growth type materials. Phase change memories are considered as a proper performing candidate for flash replacement in memory nodes. The operation of these memories is based on the resistive properties of the phase change material. This phase change material may present a low ohmic resistivity in its crystalline configuration. Nevertheless, an amorphous structure results in a resistivity which may be significantly larger, for example three orders of magnitude larger. Applying a specific thermal pulse to the cell may induce the change from crystalline to amorphous and vice versa. High temperatures with fast cooling may lead to the amorphous state, while lower temperatures and slower cooling rates may make the material crystallize.

However, phase change material can eventually crystallize spontaneously when left at room temperature, then, the amorphous state is not a stable configuration. Two different kinds of phase change material are known. Nucleation type materials and fast growth materials. The difference between both groups is the crystallization dynamic. Nucleation type materials crystallize by the nucleation and posterior growing of crystal nuclei inside the amorphous material. In a fast growth material the nucleation phenomena may be smaller or marginal, instead, crystallization phenomena may be dominated by the boundary displacement of the crystalline interface towards the amorphous part of the material.

In order to improve the data retention particularly of a grow type phase change material, embodiments of the invention may retard this crystallization phenomenon. In the case of a fast growth material, embodiments of the invention isolate, via one or more barriers, the amorphous region of the phase change material from the crystalline region (and surrounding materials). In that way, the crystalline boundary may be prevented from moving towards the amorphous area, reducing the crystallization process to the marginal nucleation dynamics, and therefore, enlarging the data retention of the phase change memories.

According to an exemplary embodiment of the invention, a phase change region may be provided in which the phase change material is barred in order to produce a discontinuity between two lattice orders (amorphous lattice and any kind of crystalline order). According to an exemplary embodiment of the invention, a phase change material line is provided in which the line is delimited by barriers of a different material or composition than the phase change line, in order to contain the amorphous region between these barriers. According to another exemplary embodiment of the invention, as an addition or as an alternative to the provision of a barrier, a selectively differentiated phase change line may be provided for control over threshold voltage, data retention improvement and power reduction. For instance, phase change line cells may require a reset current inversely proportional to its length. Hence, longer line cells may require less current due to a better heat confinement in the middle of the line which may be highly beneficial for integration and scalability. Nevertheless, long lines may tend to present larger amorphous spots, what may cause larger threshold voltages required for a set operation. In an embodiment, the data retention of the material may be increased, and at the same time the current needed for operation may be decreased without increasing the threshold voltage. In order to improve the data retention of a grow type phase change material, it may be desirable to retard the crystallization phenomenon. Particularly in the case of a fast growth material, the embodiment may be capable to eliminate or suppress the crystallization initialization points. Those are the crystalline/amorphous interfaces. One exemplary gist is to differentiate (for instance by implantation) edges of the line cell such that the material there has different properties than material in the center of the line. The material in the line center may undergo amorphization with normal operation, but the edges of the amorphous spot may be limited by the implanted material, which may be designed to have different properties, lattice constant, etc. Therefore, the interface crystalline/amorphous may be suppressed. In that way, due to the absence of a crystalline boundary, it will not be able to move towards the amorphous area, reducing the crystallization process to the marginal nucleation dynamics, and therefore, enlarging the data retention of the phase change memories. On the other hand, this differentiation (i.e. amorphous implantation) may reduce the length of the line that can undergo phase change while keeping the physical length of the line constant. In such a way it may be possible to benefit from the good heat confinement of long lines, but thanks to the reduced switchable length of the line, it is possible to keep the amorphous mark reduced and the threshold voltage under control.

Next, further exemplary embodiments of the electronic component will be explained. However, these embodiments also apply to the method of manufacturing an electronic component.

The barrier may be configured as a crystallization barrier for suppressing spontaneous (i.e. not externally induced) unintentional crystallization of the convertible structure. The barrier may confine a region of the convertible structure which region may be treated to consist of a single phase, thereby preventing undesired recrystallization, for instance by boundary motion.

The barrier may comprise an electrically conductive material. This may be appropriate since such a conductive barrier does not disturb the programming and readout procedure due to small ohmic losses, which result from such a conductive barrier. However, the barrier may also be an electrically insulating material, for instance a tunnel barrier, allowing electric current carriers such as electrons to tunnel through the insulating layer. It is also possible that a semiconductor material is used for the barrier, which may have the advantage that the manufacture of the barrier may be compatible with semiconductor technology such as CMOS procedures.

The convertible structure may be shaped as a line (for instance having a layer-like shape extending basically horizontally in a monolithically integrated embodiment), and the barrier may comprise a layer traversing (or intersecting) the line. For example, such a barrier layer may have an orientation, which is perpendicular to a for instance horizontally applied line shaped convertible structure.

More particularly, the convertible structure may be shaped as a line and the barrier may comprise two (or more) layers traversing the line and delimiting one or more sub-portions of the convertible structure. Therefore, the line shape of the convertible structure may define a stripe or the like which may be separated into islands with perpendicularly oriented barriers so that it can be ensured that at least one or even each island can be programmed to contain only a single phase, thereby preventing particularly boundary motion based recrystallization procedures.

The barrier may be configured for delimiting a sub-portion of the convertible structure, for instance in an island-like manner in which the convertible structure is completely surrounded by separation material separating the convertible material from other convertible material regions. The electronic component may further comprise a control unit (such as a user-controlled or machine-controlled electric signal source) adapted for applying an electric signal to the convertible structure to selectively convert the entire delimited sub-portion of the convertible structure into one of the at least two states (see FIG. 9, for example). By arranging the programming scheme of the control unit such that a programming current/voltage heats the entire convertible material of the region confined between the delimiting barriers, basically all molecules of such an island may be brought to the same state. Thus, boundary displacement based recrystallization may be prevented so that it may be ensured that the retention time of the arrangement is high.

The retention enhancement structure or the convertible structure may comprise a material section being altered (or modified) as compared to the other one of the retention enhancement structure and the convertible structure for suppressing conversion between different ones of the at least two states in the absence of heating. In other words, in one embodiment, the retention enhancement structure may comprise a material section being altered as compared to the convertible structure for suppressing conversion between different ones of the at least two states in the absence of heating. Therefore, the retention enhancement structure has originally been material of a convertible structure, but has been modified to change a property of the structure to form a retention enhancement structure which does no longer have the properties of the convertible structure. In an alternative embodiment, the convertible structure comprises the material section being altered as compared to the retention enhancement structure for suppressing conversion between different ones of the at least two states in the absence of heating. Therefore, in such an embodiment, the entire structure formed of the retention enhancement structure and the convertible structure has originally been of retention enhancement material which has, in a specific spatial section, been modified so as to form there locally a convertible structure. By taking this measure, it is possible to obtain a high effective length of the conductive region between the two electrodes, thereby reducing threshold voltage and required power for switching the convertible structure between different phase states. Simultaneously, the retention time may be significantly improved since the convertible structure does not comprise any interface of different phase states which may conventionally be a seed for undesired spontaneous phase changes.

Particularly, the material section may comprise chemically modified material, doped material, material being altered by implantation of ions, atoms, molecules or larger particles, or material having an altered lattice constant or other lattice property. Therefore, by triggering a chemical reaction in a portion of the electronic component, retention enhancement material may be converted into the convertible structure, or vice versa, to form two distinguishable sections. Doping or implantation of material, for instance of an n-type or a p-type, may be a further measure which can be taken for forming two distinguishable sections without a crystalline/amorphous interface of a convertible material. Changing lattice properties such as a lattice constant (i.e. a distance between adjacent lattice atoms) may also be a measure for forming two distinguishable sections.

In an embodiment, the retention enhancement structure may be embedded between the first electrode and/or the second electrode on the one hand and the convertible structure on the other hand. For example, there may be an order first electrode—retention enhancement structure—convertible structure—retention enhancement structure—second electrode, or a sequence first electrode—retention enhancement structure—convertible structure—second electrode, or first electrode—convertible structure—retention enhancement structure—second electrode. In all these configurations, the probability of the generation of a two phase boundary may be reduced.

In an embodiment, the convertible structure may be shaped as a line (such as a linear stripe). The retention enhancement structure may form part of the line and may comprise two end sections of the line each of which being sandwiched between one of the electrodes and the centrally arranged convertible structure. By such a sandwich arrangement having five different portions (two electrodes, two retention enhancement sub-portions and the convertible structure at a central position) may provide a symmetric structure with the convertible structure in the middle. Therefore, by applying a programming pulse between the two electrodes may result in a power distribution or heat dissipation distribution along the sequence which has a maximum at the centrally arranged convertible structure. Therefore, the electric switching energy may be deposited efficiently at the desired destination, i.e. the centrally arranged convertible structure.

A thermal conductivity of the convertible structure may be lower than a thermal conductivity of the retention enhancement structure. By taking such a measure, it may be ensured that a majority of the power introduced into the system during programming is in fact used for heating the convertible structure thereby allowing to trigger a local phase change, as desired.

The retention enhancement structure and the convertible structure may be arranged relative to one another so that the electronic component is free of any interface between crystalline material of the convertible structure and amorphous material of the convertible structure, in a scenario in which no programming electrical signal is present. Therefore, the arrangement of these components may be specifically adjusted so that no crystalline/amorphous boundary is produced and that any unintentional phase change may be safely prevented.

In the following, further exemplary embodiments of the method will be explained. However, these embodiments also apply to the electronic component.

In one embodiment, the forming of the retention enhancement structure may comprise forming a barrier within the convertible structure configured for suppressing conversion between different ones of the at least two states in the absence of heating. Such a barrier may formed as a thin dielectric layer between adjacent portions of the convertible structure.

Additionally or alternatively, the forming of the retention enhancement structure may also comprise altering a material section of the convertible structure into the retention enhancement structure for the suppressing conversion between different ones of the at least two states in the absence of heating. Thus, it is possible that material which has originally been part of the convertible structure is locally made subject of a specific treatment to be converted into the retention enhancement structure. This retention enhancement structure may be chemically and/or physically different from the original convertible structure but may still have some similarities with the convertible structure. Therefore, by confining the convertible structure in a local way, it may be prevented that undesired spontaneous phase change takes place.

However, the forming may also comprise altering a material section of the retention enhancement structure into the convertible structure for suppressing conversion between different ones of the at least two states in the absence of heating. In such an embodiment, the convertible structure has originally been part of the retention enhancement structure which is then converted selectively into phase change material. By taking this measure, particularly the same effects can be achieved as in the previous embodiment.

Converting a material section of the retention enhancement structure or the convertible structure into the other one of these structures may be performed by implanting a dopant or the like using a mask. For instance, such a mask may cover only portions of the later convertible structure which is afterwards formed by doping in exposed regions, whereas a remainder of the retention enhancement structure may be prevented from being implanted using a patterned photoresist or the like. This procedure can be changed in a way that the retention enhancement structure is formed on basis of the convertible material which is covered by the mask. Therefore, implanting may either convert convertible material into retention enhancement material, or vice versa.

In an embodiment, a phase change line may be provided in which one or both of the edges of the line are from a different material or composition or differ in its structure from the material, composition or structure of the material of the center of the line. A phase change line and a method of making two or more different regions are provided, based on different material, structure or composition, in a phase change line, by means of adding an extra mask followed by implantation. The effective length of such a phase change line may be decreased by decreasing the size of the effective or active phase change material. Data retention in such phase change lines may be increased by suppressing crystalline/amorphous interfaces of the same material. A selective implantation into a phase change line cell may be performed in order to create one or more different regions. A selective deposition into a phase change line cell may be performed in order to create one or more different regions. Any selective process that results in the creation of a phase change line with one or more regions in which the material, properties, composition or structure differ from each other may be appropriate. A horizontal line cell may be provided with top, bottom and/or lateral interfaces doped through any method (implantation or deposition plus annealing), in order to create a different region in the interfaces phase change material/dielectric than the core of the line. A horizontal phase change line cell may be provided with both edges implanted in order to create a different region than the central region. A horizontal phase change line cell may be provided with a central region implanted in order to create a different region than the edges. A horizontal line cell with both edges doped through deposition plus annealing may be provided in order to create a different region than the central region. A horizontal line cell with a central part being doped through deposition plus annealing may be provided in order to create a different region than the edges. A horizontal line cell with top, bottom and/or lateral part doped through any method (implantation or deposition plus annealing) may be provided in order to create a different region in the interfaces phase change material/dielectric than the core of the line.

Embodiments of the invention may be applied to any desired structure such as a horizontal cell in which the convertible structure extends horizontally between two electrodes, a vertical line in which a vertical sandwich structure of the two electrodes with an intermediate convertible structure is obtained, and also an Ovonic cell architecture (see FIG. 13, for instance) is possible.

According to an exemplary embodiment of the invention, a vertical phase change line may be provided with at least two barriers delimiting a phase change on top and down.

According to an exemplary embodiment of the invention, an Ovonix type cell may be provided, with the active phase change region surrounded by a barrier.

According to an exemplary embodiment of the invention, a horizontal phase change line may be provided in which barriers are set in the edges of the line to delimit a phase change active region.

According to an exemplary embodiment of the invention, a pore phase change cell may be provided, in which the active phase change area is limited by barriers.

According to an exemplary embodiment of the invention, a spacer phase change cell may be provided in which barriers limit the active phase change area.

According to an exemplary embodiment of the invention, a cross spacer phase change cell may be provided in which the active phase change area is limited by barriers.

According to an exemplary embodiment of the invention, a phase change memory may be provided to improve their data retention.

In many phase change materials, the crystalline state is more stable than the amorphous state. Particularly for such materials, it may be advantageous to include barriers of a different material inside of the phase change material so that undesired recrystallization can only occur outside of a phase change island being small enough to be free of interfaces between crystalline domains and amorphous domains, thereby preventing boundary displacement based recrystallization.

Embodiments of the invention may be particularly advantageous for fast growth type phase change materials. However, chalcogenides alloys present in most of the cases a combination of fast growth crystallization dynamics and nucleation crystallization dynamics. Therefore, the inclusion of barriers may improve the retention behaviour for a broad range of chalcogenide alloys. An example for a nucleation dominated phase change material can be a combination of germanium antimony and tellurium, while a fast growth dominated phase change material may be a doped (for instance indium, phosphor, silicon,) combination of germanium, tellurium, and antimony.

The convertible structure may form a thermo-dependent structure, particularly a phase change structure which is convertible between at least two phase states. Thus, under the influence of heat which may be generated by ohmic losses of a programming current flowing through the phase change structure and/or electrodes connected thereto, the switch between the two phases can be initiated. Thermal energy may also be supplied via electromagnetic radiation. However, thermal energy can be also supplied by a contiguous structure/heater.

Particularly, the phase change structure may be adapted such that a value of the electrical conductivity differs between the two phase states. In one of the at least two phase states, the phase change structure may be electrically conductive (for instance essentially metallically conductive). In the other phase state, the electrical conductivity may be larger or lower than in the first state, for instance the phase change structure may be superconductive or may be semiconductive or may be isolating or may be conductive as well with a modified value of conductivity. In a normal operation of the electronic component, the function of the electronic component will be influenced, will be defined or will depend on the present value of the electrical conductivity of the phase change structure. This may allow to manufacture memory cells, switches, actuators, sensors, etc. using the different value of the electrical conductivity of the phase change structure in the different phase modes.

A current pulse or a current signal may generate heat in a convertible material to thereby change its phase state and consequently its value of the electrical conductivity. The applied current pulses may have a certain shape (for instance may have a fast raising edge and a slow falling edge, or may have a raising edge which is curved to the right and a falling edge which is curved to the left) and may be characterized by different parameters (such as current amplitude, pulse duration, etc.). By adjusting the pulse parameters, it is possible to control whether the phase change material is converted into a crystalline phase or is converted into an amorphous phase. Very high temperatures with rapid cooling down may result in an amorphous phase. A smaller increase in temperature or slower cooling down may lead to a crystalline phase.

The phase change structure may be adapted such that one of the two phase states relates to a crystalline phase and the other one of the two phase states relates to an amorphous phase of the phase change structure. Such a material property can be found in chalcogenide materials. A chalcogenide glass may be used which is a glass containing a chalcogenide element (sulphur, selenium or tellurium) as a substantial constituent. Examples for phase change materials are GeSbTe, AgInSbTe, InSe, SbSe, SbTe, InSbSe, InSbTe, GeSbSe, GeSbTeSe or AgInSbSeTe. Embodiments of the invention may be particularly advantageous for phase change material of the fast growth type.

The electronic component may comprise an electric sensing circuitry adapted for sensing the different electrical properties of the convertible structure in different ones of the at least two states. For instance, a test voltage may be applied to the convertible structure, and a current flowing along the convertible structure will depend on the phase state of the convertible structure, since the electrical conductivity is different in the crystalline and in the amorphous phase. Such a sensing circuitry may also include selection transistors or other kinds of switches, which selectively enable or disable access to a particular electronic component of an array of electronic components. Thus, a respective selection transistor may be assigned to each one of the electronic components.

The electronic component may be adapted as a memory device. In such a memory device, the information of one or more bits may be stored in the present phase of the phase change material, particularly depending on the present one of two or more phase states of the phase change structure.

The electronic component may also be adapted as a memory array, that is a configuration of a (large) plurality of memory devices of the aforementioned type. In such a memory array, the memory cells may be arranged in a matrix-like manner and may be controlled via bit lines and word lines with transistors serving as switches to get or prevent access to desired individual memory cells and memory devices. The multiple memory cells may be monolithically integrated in a common (for instance silicon) substrate.

The electronic component may also serve as an actuator, since a change of the electrical conductivity of the phase change structure may result in a modification of an actuation signal.

It is also possible to adapt the electronic component as a microelectromechanical structure (MEMS). An electrical signal modified by a phase change of the convertible material may result in a specific motion of a movable component of the microelectromechanical structure (MEMS).

It is clear that the modification of the phase change material, and therefore of its electrical conductivity, may be used to construct controllers, switches, transductors, etc.

For any method step, any conventional procedure as known from semiconductor technology may be implemented. Forming layers or components may include deposition techniques like CVD (chemical vapour deposition), PECVD (plasma enhanced chemical vapour deposition), ALD (atomic layer deposition), or sputtering. Removing layers or components may include etching techniques like wet etching, vapour etching, etc., as well as patterning techniques like optical lithography, UV lithography, electron beam lithography, etc.

Embodiments of the invention are not bound to specific materials, so that many different materials may be used. For conductive structures, it may be possible to use metallization structures, silicide structures or polysilicon structures. For semiconductor regions or components, crystalline silicon may be used. For insulating portions, silicon oxide or silicon nitride may be used.

The structure may be formed on a purely crystalline silicon wafer or on an SOI wafer (Silicon On Insulator).

Any process technologies like CMOS, BIPOLAR, BICMOS may be implemented.

The aspects defined above and further aspects of the invention are apparent from the examples of embodiment to be described hereinafter and are explained with reference to these examples of embodiment.

### BRIEF DESCRIPTION OF THE DRAWINGS

The invention will be described in more detail hereinafter with reference to examples of embodiment but to which the invention is not limited.

FIG. 1 shows an electronic component according to an exemplary embodiment of the invention.

FIG. 2 shows a memory array according to an exemplary embodiment of the invention.

FIG. 3 schematically illustrates the erasure (crystallization) process of two types of phase change materials, namely nucleation-driven erasure and growth-driven erasure.

FIG. 4 shows TEM images of amorphous marks in a phase change disc after recording and after different annealing procedures.

FIG. 5 shows, for a phase change line memory, thermal simulation of a programming operation into a phase change line cell (FIG. 5A), crystallization dynamics of an amorphous phase change line made of grow-type phase change material (FIG. 5B), and a description of an embodiment of a phase change line cell (FIG. 5C).

FIG. 6 shows TEM pictures of an amorphous phase change line (left) and crystalline phase change line (right).

FIG. 7 shows a diagram illustrating a recrystallization time of three phase change lines with the same dimensions and different initial resistances. Larger initial resistances indicate larger amorphous areas. Larger amorphous areas lead to longer retention as expected from theory.

FIG. 8 shows a diagram illustrating a temperature for ten years retention versus amorphous size.

FIG. 9 shows a memory cell, in which two crystallization barriers are situated to avoid any R−/R+ interface according to an exemplary embodiment of the invention.

FIG. 10 shows a vertical line cell made with crystallization barriers according to an exemplary embodiment of the invention.

FIG. 11 shows a process summary of a memory cell according to an exemplary embodiment of the invention.

FIG. 12 shows a process summary of a memory cell with a barrier made of a doped phase change material according to an exemplary embodiment of the invention.

FIG. 13 shows an Ovonix type cell with a barred phase change region to avoid growth crystallization according to an exemplary embodiment of the invention.

FIG. 14 illustrates an electronic component according to another exemplary embodiment of the invention.

FIG. 15 is a diagram illustrating that reset currents are different for different phase change dimensions.

FIG. 16 is a diagram illustrating a threshold voltage distribution for different phase change cell architectures.

FIG. 17 to FIG. 20 show different layer sequences obtained during a method of manufacturing an electronic component according to an exemplary embodiment.

FIG. 21 to FIG. 24 illustrate different layer sequences obtained during a method of manufacturing an electronic component according to another exemplary embodiment.

### DESCRIPTION OF EMBODIMENTS

The illustration in the drawing is schematical. In different drawings, similar or identical elements are provided with the same reference signs.

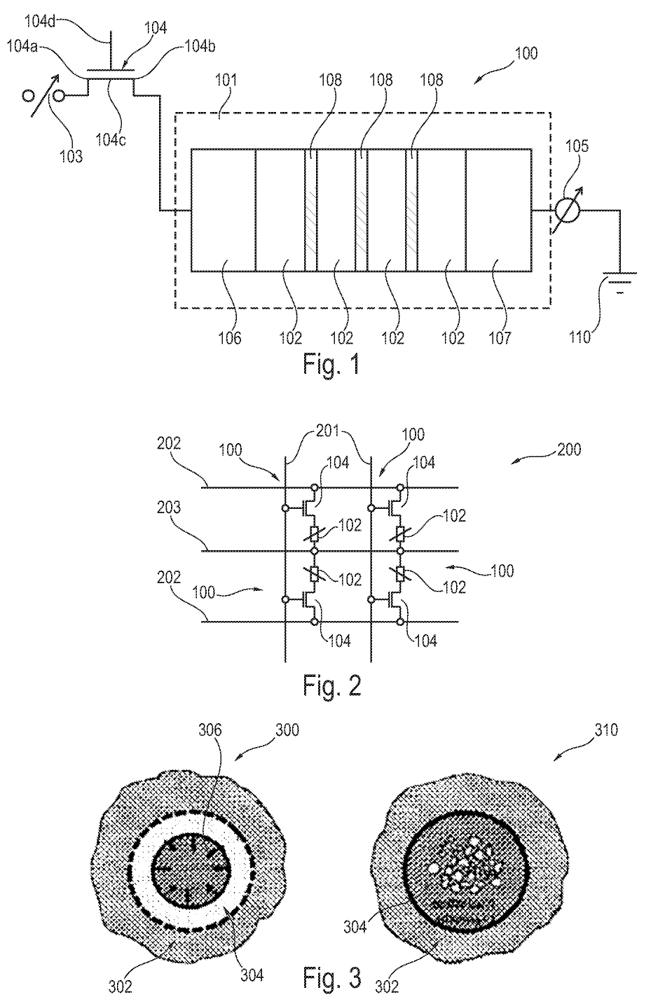

In the following, referring to FIG. 1, a memory cell 100 according to an exemplary embodiment of the invention will be explained.

The memory cell 100 comprises a silicon substrate 101 and a pattern layer of a phase change material structure 102 arranged in a planar manner on a surface of the silicon substrate 101. The phase change material 102 is convertible between a crystalline state and an amorphous state by heating and has different electrical properties (particularly different values of the conductivity) in the different states.

As can be taken from FIG. 1, the phase change material 102 has a basically rectangular shape.

Under the influence of an electric current which may flow between a first electrode 106 and a second electrode 107 through the phase change material structure 102, it is possible to detect the present state of the phase change material 102 by means of a small sensing current, and it is possible to switch between the states of the phase change material 102 by means of a larger programming current.

An electric sensing circuit formed by coupled components 103 to 105 is provided for sensing the different electrical properties of the phase change material 102 and for switching between different ones of the two states. For this purpose, a current source 103 having a variable current is provided. A switch transistor 104 is provided having the source/drain regions 104a, 104b and the channel region 104c between the current source 103 and the first electrode 106. By modifying a switch voltage applied to a gate 104d of the transistor 104, it is possible to select or deselect the memory cell 100 which may be part of a memory array such as the memory array 200 shown in FIG. 2.

When the switch 104 is closed, a current generated by the current source 103 may flow from the first electrode 106 through the convertible structure 102 to the second electrode 107. The flowing voltage or current value may be detected or measured by a voltage or current measurement device 105, which is connected between the second electrode 107 and a reference potential such as a ground potential 110.

In the present embodiment, only the components 106 to 108, 102 are formed on the substrate 101. However, it is also possible that the switch transistor 104, the current source 103 and/or the measurement device 105 is/are arranged on or is/are monolithically integrated in the silicon substrate 101.

The electronic component 100 further comprises a barrier structure 108 embedded within the convertible structure 102 (for instance being entirely or basically entirely surrounded by material of the convertible structure 102) configured for suppressing conversion between different ones of the at least two states of the convertible structure 102 in the absence of heating. The barrier 108 is formed as a plurality of layers which are arranged parallel to one another and perpendicular to the paper plane of FIG. 1 and therefore divide the convertible structure 102 into several separate or discontiguous sections. Each of the sections delimited by the barrier structure component 108 are sufficiently narrow or small to ensure that during a programming procedure, the entire volume of such a section 102 can be brought into exactly one state, so that particularly when the convertible structure 102 is made of a fast growth type phase change material, the retention time may be significantly increased.

FIG. 2 shows a memory array 200 being a matrix-like arrangement of a plurality of memory cells 100.

The phase change memory array 200 comprises bit lines 201 via which electrical signals are applied to gate terminals of the switch transistors 104, to selectively turn them on or off. Furthermore, the memory array 200 comprises word lines 202 via which reading or programming currents may be applied to the phase change material structure 102 of the respective memory cells. A ground line 203 is shown as well.

In the following, some basic recognition of the present inventor will be explained based on which exemplary embodiments of the invention have been developed.

It is expected that future nodes will require smaller dimensions. The retention time of a phase change memory based on a fast growth material may be determined by the size of the amorphous area. Then, the scaling of a phase change area will impact in its retention. Without wishing to be bound to a specific theory, it is presently believed that in these materials the crystallization dynamics are based on the movement of the crystalline-amorphous interface and on the recoiling of the amorphous zone. A smaller amorphous area may lead to a faster crystallization.

According to an exemplary embodiment of the invention, the fact is exploited that an absence of a crystalline/amorphous interface may retard the fast growth process. In the case this interface does not exist, crystallization may require a nucleation to generate a valid interface. Since this phenomenon may involve higher activation energy for fast growth type materials, the crystallization may be effectively retarded. This may lead to an improved retention time.

FIG. 3 shows the crystallization dynamics of an amorphous dot written in a nucleation-type material and in grow-type material.

On the left-hand side of FIG. 3, a structure 300 is shown which illustrates a growth-driven erasure procedure. A crystalline background 302 accommodates a written amorphous mark 304. As indicated by arrows 306, such a structure may have the tendency to recrystallize spontaneously. On the right-hand side of FIG. 3, a nucleation-driven erasure structure 310 is shown. Here, an accumulation and a nucleation of written amorphous marks 304 takes place.

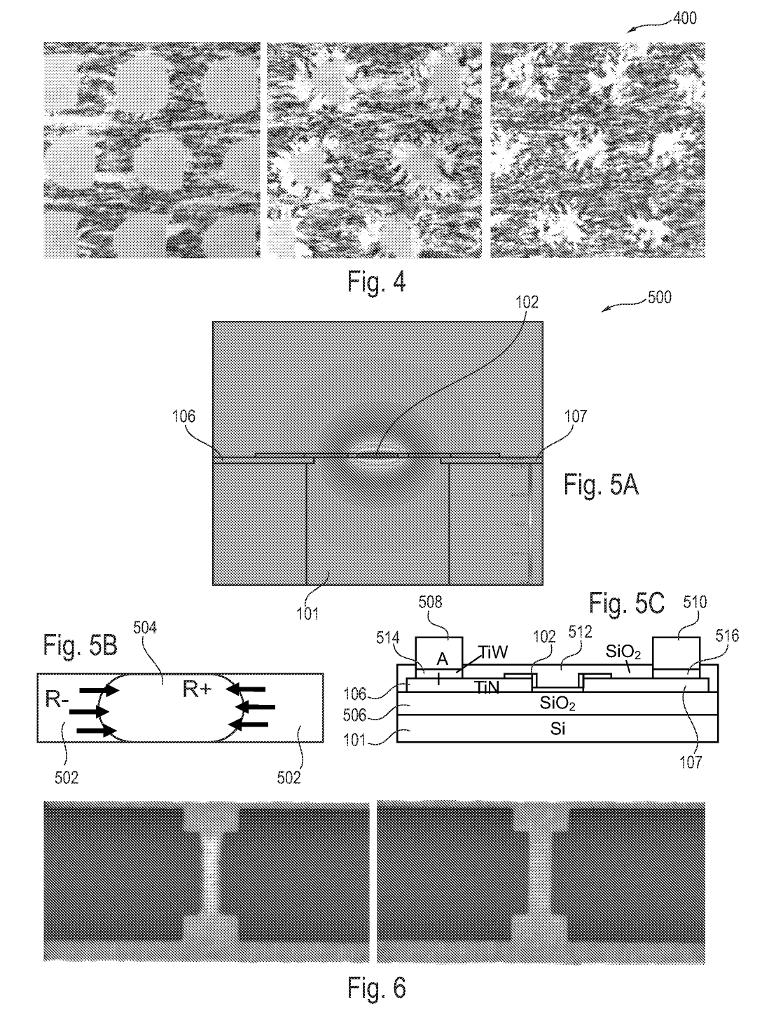

The phenomenon illustrated in FIG. 3 has been proved experimentally—see FIG. 4.

FIG. 4 shows TEM images 400 of amorphous marks recorded in a phase change disk based on doped eutectic SbTe after recording (left-hand side image), after annealing for one hour at 165° C. (central image), and after annealing for one hour at 175° C. (right-hand side image). FIG. 4 shows that the amorphous marks are recrystallized by growth of the crystalline edge towards the marks center.

In one configuration of a phase change memory, an amorphous mark is not written in a dot, but in a line laying between two electrodes, as depicted in FIG. 5.

FIG. 5A shows a thermal simulation of a programming operation into a phase change line memory cell 500. Thus, FIG. 5A illustrates a phase change line memory 500 in a cross-sectional view.

FIG. 5B illustrates crystallization dynamics of an amorphous phase change line made of grow-type phase change material. In FIG. 5B, it is shown schematically how a crystalline phase 502 (R−) is the starting point for recrystallizing an amorphous portion 504

(R+). FIG. 5B clearly shows that in this concept the crystallization (R−) of the amorphous (R+) area 504 is due to a recoiling of the amorphous/crystalline (R+/R−) boundary.

FIG. 5C illustrates an embodiment of a phase change line cell 500 having wiring elements 508, 510 contacting electrodes 106, 107 via intermediate layers 514, 516, and a silicon oxide layer 506 between the silicon substrate 101 and the active portion, as well as a silicon oxide top structure 512 covering the active region.

FIG. 6 shows a SEM picture of the concept described in FIG. 5. FIG. 6 left shows a line in its amorphous state (R+), while FIG. 6 right shows the same line in the crystalline state (R−).

By changing the length of the amorphous area as showed in FIG. 6, one can observe the differences in crystallization times. According to theory, a smaller amorphous mark made of grow phase change material will crystallize faster than a larger amorphous area. To know the length of the amorphous area (without need of TEM analysis) the resistance of the line can be measured. Since the amorphous material is more resistive than the crystalline, a higher resistance will indicate a larger amorphous area. Then, programming three lines with the same dimensions to different resistances, the crystallization time can be measured. Larger resistances are expected to crystallize later, meaning a longer data retention time.

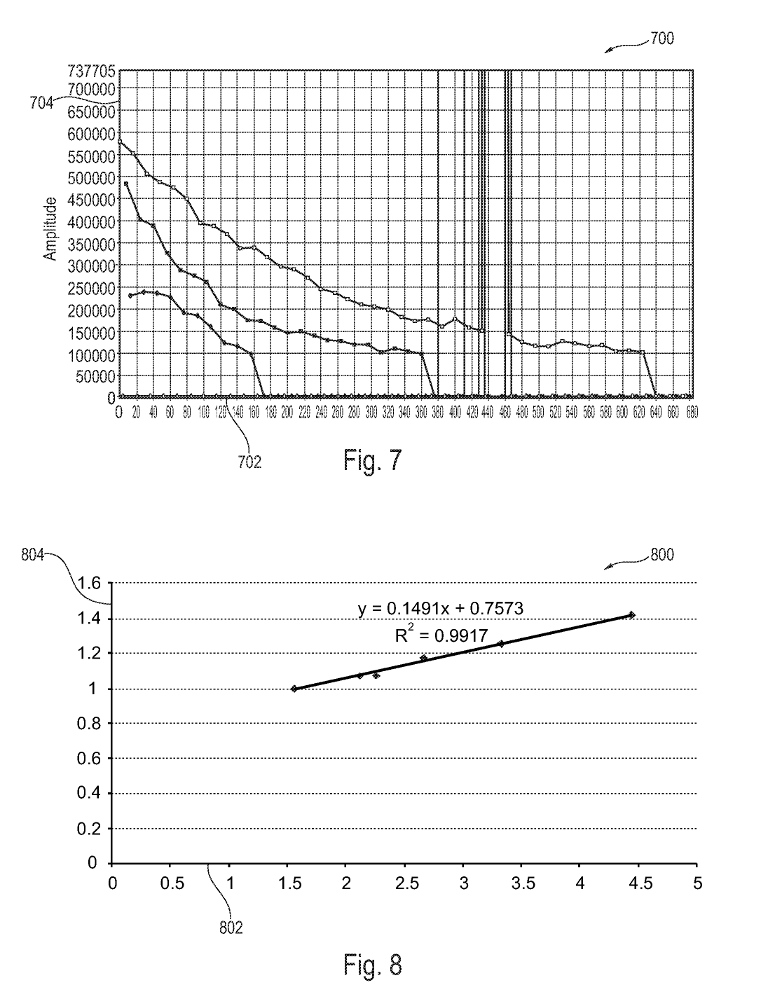

All this is experimentally confirmed as shown in FIG. 7. FIG. 7 illustrates a diagram 700 having an abscissa 702 along which the time is plotted. Along an ordinate 704 a resistance value is plotted.

Three lines with identical dimensions are programmed to different resistances, larger resistances corresponding to larger amorphous areas. The resistance of the sample is measured at high temperature to accelerate the crystallization process. The gradual decrease in resistance shows the crystallization process of the line. Larger initial resistances lead to a longer crystallization time.

FIG. 8 is the result of several experiments similar to the one indicated in FIG. 7. FIG. 8 shows a diagram 800 having an abscissa 802 along which an amorphous size is plotted (squares). Along an ordinate 804, a normalized temperature for data retention of 10 years is plotted.

FIG. 8 shows that a reduction in the amorphous size (reduction in the number of amorphous squares) leads to a reduction in the data retention (crystallization) temperature. The data retention temperature is the temperature for which retention of 10 years is expected. The smaller amorphous marks can stand lower temperatures, formulated in other way, for the same constant temperature, the data retention of small amorphous marks is shorter than the larger amorphous marks.

In order to overcome this issue, embodiments of the invention eliminate the crystalline/amorphous boundary. Since in a line cell there are only two of these boundaries (in the sides where the line is contacted with the electrode), this can be done by ‘cutting’ the phase change line with a different material, which may avoid the crystalline/amorphous boundary.

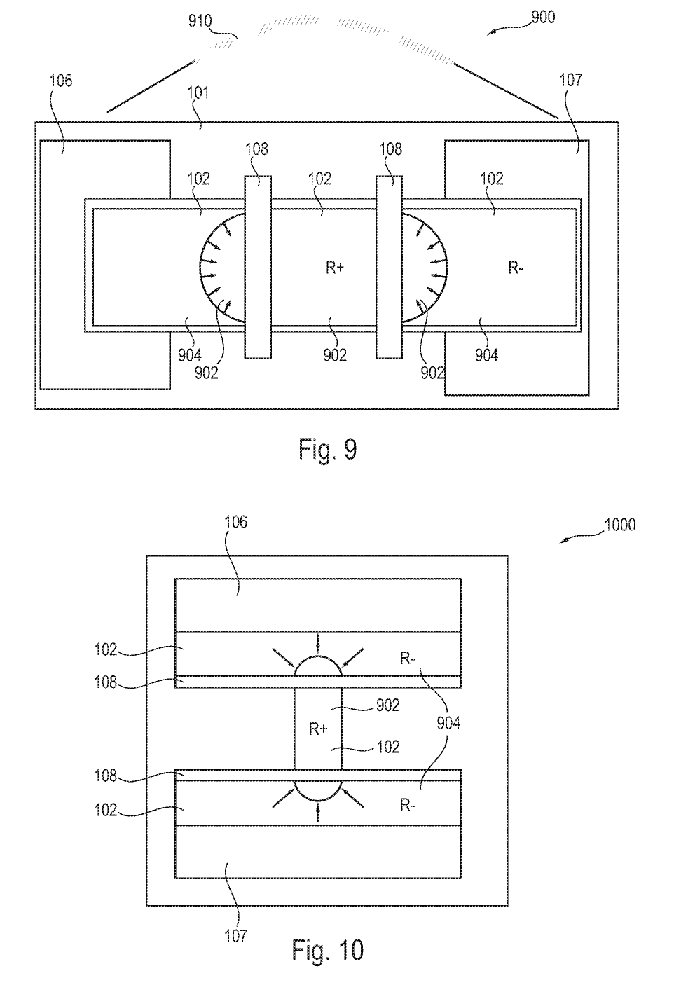

FIG. 9 plots a memory cell 900 according to an exemplary embodiment of the invention.

FIG. 9 has amorphous portions 902 and crystalline portions 904 of phase change material 102, wherein arrows in FIG. 9 indicate undesired recrystallization procedures. The structures 108 serve as a recrystallization barrier.

Two barriers 108 have been situated in the line 102 to break the continuity of it. A programming pulse will produce a thermal profile as showed in the curve above the line of FIG. 9, where the stripped part indicates where the temperature of the line 102 is high enough to amorphize it. The amorphous part 902 extends over the barrier elements 108. Then, no crystalline/amorphous interface is inside the barriers 108. So, crystallization of the area within the barriers 108 will be driven by nucleation. A retarded crystallization is achieved, leading to a larger data retention time.

Data retention in grow type phase change material depends on the recoiling of the amorphous area 902 from the amorphous/crystalline boundary. In order to retard crystallization, embodiments of the invention eliminate the fast grow movement of the boundaries. In this case, crystallization will be conditioned to the nucleation of crystalline nuclei inside the amorphous area 902, and its posterior growth. Nevertheless, in grow type materials this nucleation phenomenon is a marginal effect. This way, crystallization times and data retention may be improved.

Since in line cell 900 there are only two of these boundaries (in the sides where the line 102 is contacted with the electrodes 106, 107), by ‘cutting’ the phase change line 102 with a different material 108, it may be possible to avoid or suppress the crystalline/amorphous boundary.

FIG. 9 shows an example and possible embodiment of the invention. Two barriers 108 have been situated in the line 102 to break the continuity of it. A programming pulse will produce a thermal profile as shown schematically in a curve 910 above the line 102 of FIG. 9, where the stripped part indicates where the temperature of the line 102 is high enough to amorphize it. The amorphous part 902 extends over the barrier elements 108. Then, no crystalline/amorphous interface is inside the barriers 108. So, crystallization of the area within the barriers 108 will be driven by crystallization. A retarded crystallization is achieved, leading to a larger data retention time.

Crystallization barriers 108 can be made of any material, conductor, semiconductor or insulator. A conductor type material may be preferred since it does not affect the electrical continuity of the cell 900. In addition, its good thermal conduction can make the heat to transfer outside the barred region to further extend the amorphization of the line 102. Choosing the same material as the electrode 106, 107 may be an option. A semiconductor material can be used due to the fact of its good electrical conduction and bad thermal conduction (as for instance another kind of phase change material with a very high retention, or from the nucleation type). In this case the heat confinement inside the barred region may be even better, reducing the power needed for operation. An insulator material may have a similar effect as the semiconductor, nevertheless, the resistance of the line 900 in the crystalline phase may be high due to the poor electrical conductivity of the insulator. This can cause issues in the differentiation of the amorphous and crystalline resistance. Nevertheless, if a good choice is made, this solution can be used to greatly decrease the power used for operation, since the thermal conductivity of this insulator is extremely high, confining the heat in a more efficient way. Another issue related to the use of insulating material is the reliability, since it should stand high currents and temperatures. In conclusion, conductor, semiconductor or insulator materials can be used as a barrier 108.

FIG. 10 shows a memory cell 1000 according to another exemplary embodiment of the invention.

An advantage of the vertical embodiment of FIG. 10 is the facility to build the barriers 108, since they are simple layers, in which the thickness can be easily controlled.

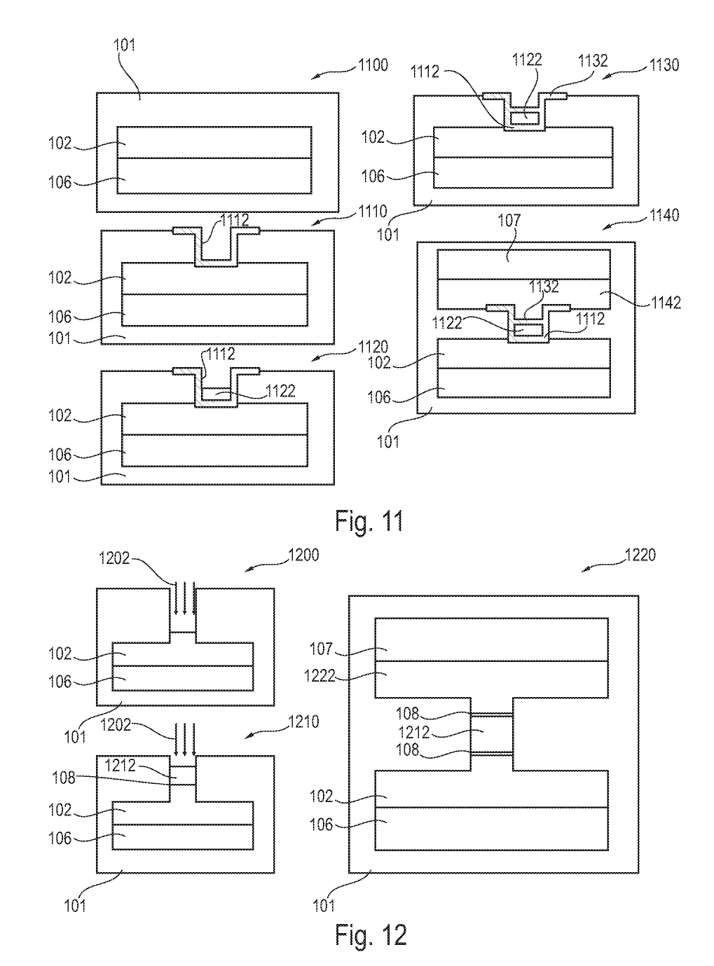

FIG. 11 illustrates a process of manufacturing a memory cell according to an exemplary embodiment of the invention.

As can be taken from a layer sequence 1100, an electrode 106 is formed on a substrate 101, and a crystalline phase change material layer 102 is formed on the electrode 106. The substrate 101 also covers the crystalline phase change material 102.

In order to obtain a layer sequence 1110 shown in FIG. 11, a trench is etched in a surface portion of the substrate 101 to expose a portion of the crystalline phase change material 102. This trench is then filled/lined with a barrier structure 1112.

A further phase change structure 1122 is deposited on the barrier structure 1112, as shown in a layer sequence 1120.

To obtain a layer sequence 1130 shown in FIG. 11, a further barrier structure 1132 is formed on the phase change material 1122 and on the barrier structure 1112.

As can be taken from a layer sequence 1140, a further phase change material structure 1142 is formed on the barrier 1132, followed by the deposition of the second electrode 107.

FIG. 11 therefore shows a summarize process for implementation of a possible embodiment.

FIG. 12 shows an even simpler embodiment on how to build the barriers for manufacturing a memory cell 1220.

A layer sequence 1200 can be obtained by forming an electrode 106 on a substrate 101, and by subsequently depositing phase change material 102 on the electrode 106, partially delimited by material of the substrate 101. In the layer sequence 1200, arrows 1202 indicate a doping procedure. As can be taken from a layer sequence 1210, a barrier 108 is thereby formed. Subsequently, a further phase change material structure 1212 is deposited on the barrier 108. As can be taken from a layer sequence 1220, a further barrier layer 108 is formed on the phase change material 1212 (by doping or deposition), which is in turn followed by the deposition of additional phase change material 1222. Subsequently, the second electrode 107 is formed.

In this case the barriers 108 are made of phase change material, which is doped in order to alter its properties and give it the desired barrier properties.

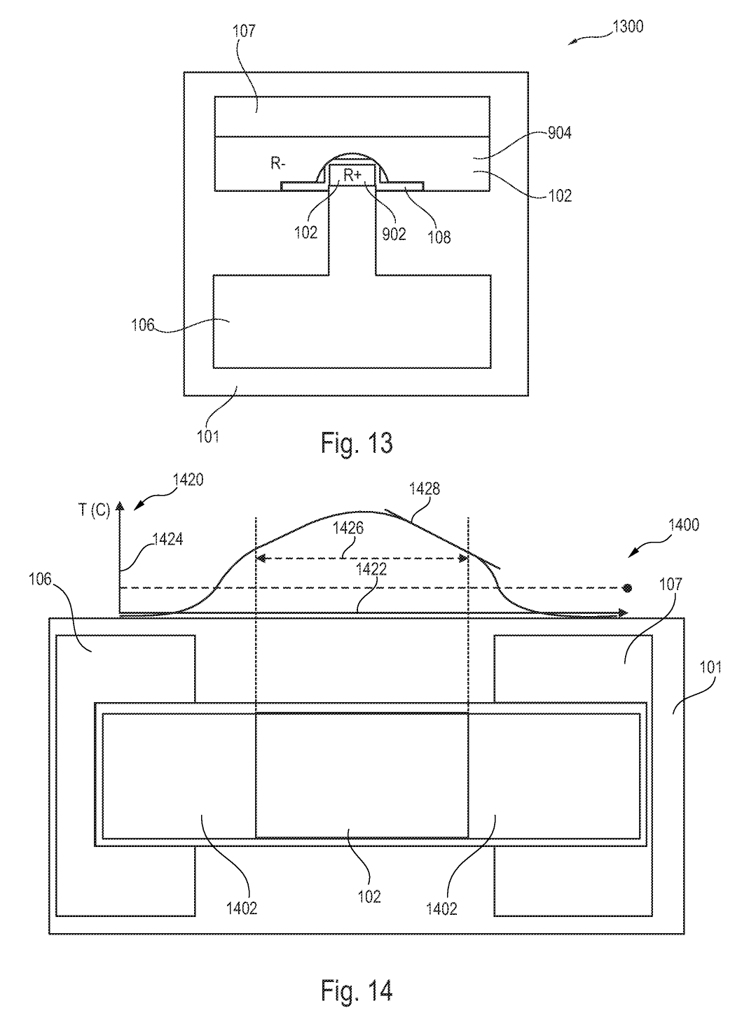

FIG. 13 shows a memory cell 1300 of the Ovonic type according to another exemplary embodiment of the invention.

FIG. 13 thus shows an embodiment applied to an Ovonic cell 1300, in which part of the active phase change region 102 is limited with barriers 108. By active area it is understood the region of the phase change material 102 that undergoes a phase transition.

According to an exemplary embodiment of the invention, it may be dispensable that the barrier is situated directly between the electrodes and the switchable material (phase change material), but these barriers may be fabricated embedded in the amorphous area so it can create a discontinuous phase change structure. In addition, for a line type cell it may be inefficient and difficult to manufacture a barrier directly between the electrode and the phase change material, leading probably to a smaller improvement in data retention due to the proximity of the electrode, which acts as a heat dissipater, and therefore makes the amorphization less homogeneous in its proximity, providing more crystalline interfaces which facilitate the crystallization and degrade the retention. In addition, embodiments of the invention may be free of pure layers as barriers, meaning that the barrier can be in the same horizontal plane as the phase change material, and in fact this may be required in the case of a line type cell.

According to an exemplary embodiment of the invention, crystallization barriers may be embedded not only as parallel layers (particularly in the case of a vertical cell) but also as horizontal barriers or perpendicular barriers, crossing and cutting the phase change layer in such a way that the final result is a discontinuous phase change horizontal line (or grid) with some intrusions of a different material acting as anti-crystallization barriers and forming intrusions in the line.

An advantage of an exemplary embodiment of the invention is that it can be used in line cells, therefore avoiding extra layers, but also in vertical cells without the necessity of sticking to a multilayer system.

According to an exemplary embodiment of the invention, it is possible to keep a material and try to protect its boundaries by a physical construction (barrier).

If embodiments of the invention are applied to, for instance, an Ovonix cell, three barriers may be used. In the case of an Ovonix type horizontal line, one barrier may be used.

There are several technical advantages achievable in connection with another embodiment which will be explained in the following.

Future nodes will require smaller dimensions. The retention time of a phase change memory based on a fast growth material is determined by the size of the amorphous area. Then, the scaling of a phase change area will impact in its data retention characteristic. Current dimensions, as well as future ones, use short cells to keep the threshold voltage under specifications. Shorter cells require more reset currents and powers. Longer cells can reduce the power needed to reset. When a selective implantation is performed in accordance with an exemplary embodiment, threshold voltages can be controlled as well.

In order to overcome this issue, an exemplary embodiment suppresses or even eliminate crystalline/amorphous boundary of a convertible material such as a phase change material. Since in a line cell there are in many cases only two of these boundaries (in both sides of the line), this can be done by manufacturing a phase change line in which the edges are made of a different material or composition, that can avoid the crystalline/amorphous boundary. This can be done by means of an implantation.

FIG. 14 shows an electronic component 1400 according to a corresponding embodiment of the invention.

In FIG. 14, a convertible structure 102 is embedded, along a current flow direction, between two retention enhancement structures 1402 each of which being directly contacted to a respective one of electrodes 106 or 107. The arrangement constituted by reference numerals 1402, 102, 1402 may be formed based on a pure phase change material line 102 extending initially over all three sections 1402, 102, 1402. Subsequently, the material of the convertible structure can be chemically modified selectively in the sections 1402, 1402 to form an altered phase change material 1402 differing from the standard phase change material 102 regarding its physical behaviour.

As can be taken from FIG. 14, the electrically conductive path between the electrodes 106, 107 is shaped as a line so that the retention enhancement structures 1402, 1402 (together with the convertible material 102) form part of the line and comprise two end sections of the line each of which being sandwiched between one of the first electrode 106 and the second electrode 107 on the one hand and the centrally arranged convertible structure 102 on the other hand. A thermal conductivity of the convertible structure 102 may be lower than a thermal conductivity of the retention enhancement structure 1402 to achieve an application of energy upon applying a programming pulse predominantly in the convertible structure 102.

The line may be embedded in an electrically insulating structure 1404 which however does not disturb a direct ohmic contact between the electrodes 106, 107 and the line.

FIG. 14 furthermore shows a diagram 1420 having an abscissa 1422 along which an extension of the line 1402, 102, 1402 is plotted and having an ordinate 1424 along which the temperature is plotted in degrees Celsius. An amorphization range 1426 (which corresponds to the convertible structure 102) indicates a spatial extension of a portion of the line which is amorphized by a corresponding programming pulse applied between the electrodes 106, 107 and flowing along line 1402, 102, 1402. By the amorphization range 1426, a melting range is delimited as well.

A programming pulse may produce a thermal profile 1428 as shown in diagram 1420. If the temperature of all the switchable phase change material 102 is over a melting temperature, all the standard phase change material 102 is amorphized. The altered phase change material 1402 is altered in such a way that it acts no longer as a phase change material, or its properties are such that the conditions used for amorphizing the standard phase change material 102 lead to no change in the altered phase change material, or its crystalline or amorphous structure are sufficiently different from the standard phase change material 102. Then, no valid crystalline/amorphous interface occurs at the edges of the line 1402, 102, 1402. So, crystallization of the standard phase change material 102 will be driven by nucleation crystallization. A retarded crystallization is achieved, leading to a larger data retention time. Hence, the altered phase change material 1402 avoids any R−/R+ interface.

With regard to the goal to achieve a power reduction, longer lines may lead to a reduced reset programming current. An advantageous aspect of exemplary embodiments is the fact that the highest temperature during programming occurs in the center 102 of the line cell 1402, 102, 1402, where the heat confinement is much better due to its distance to the electrodes 106, 107. Longer lines result in reduced reset currents since they improve the thermal isolation at the same time that they increase the electrical resistance.

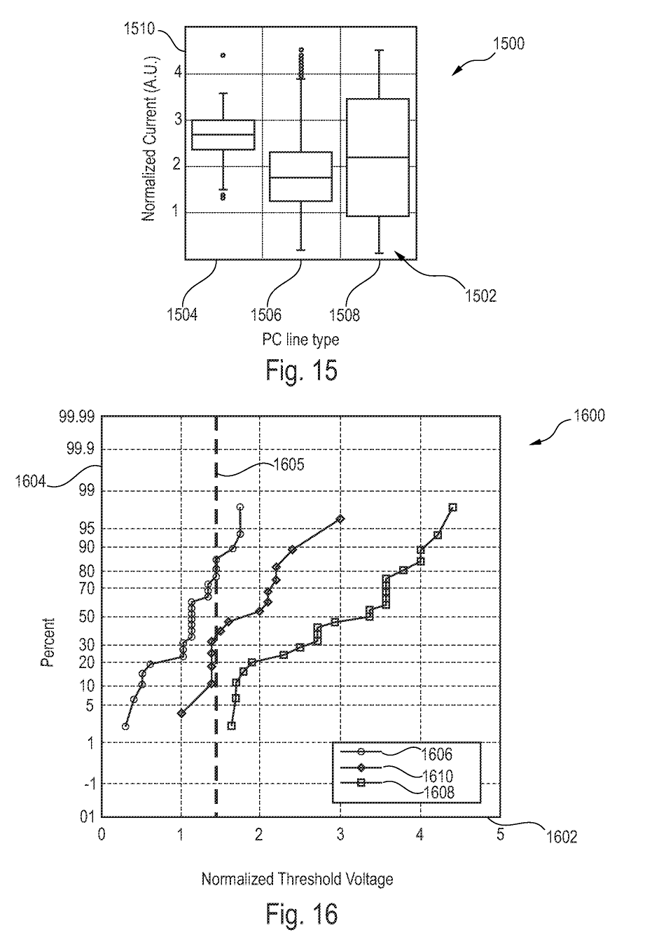

FIG. 15 shows a diagram 1500 having an abscissa 1502 along which a first phase change line type 1504 (DB5), a second phase change line type 1506 (DB13) and a third phase change line type 1508 (DB1) are plotted. Along an ordinate 1510, a normalized programming current in arbitrary units is plotted. Hence, FIG. 15 shows a reset current distribution for three different line cells DB5 having a first length, DB1 having a second length larger than the first length, and DB13 having a third length larger than the second length, respectively. Statistics have been gathered using more than thirty cells of each type. The results illustrated in FIG. 15 clearly show that reset currents are lower for longer cells (although dispersion may be broader due to side effects related to some processing issues, which are not relevant for this discussion).

FIG. 16 shows a diagram 1600 having an abscissa 1602 along which a normalized threshold voltage is plotted. Along an ordinate 1604, a percent of switched cells is plotted. A first curve 1606 relates to DB5, a second curve 1608 relates to DB13, and a third curve 1610 relates to a DB6 (having a fourth length larger than the first length and smaller than the third length). Hence, FIG. 16 shows the threshold voltage distribution of three different phase change cells. Statistics have been gathered using more than thirty cells of each type. It can be clearly seen that longer cells present a higher threshold voltage. A dotted line 1605 indicates a threshold voltage required to comply with specifications. The shorter line (DB5) present 90% of the cells with a threshold voltage on specifications, while the longer cell (DB13) shows a threshold voltage out of specifications for all cells. Intermediate cells show intermediate results, proving the threshold voltage dependence on line length.

Moreover, the threshold voltage is dependent on the amorphous size, as can be taken from equation Vt=Et*l, where Vt is the threshold voltage, Et is the threshold electric field, which is an intrinsic property of the material, and l is the length of the amorphous mark. Therefore, longer lines, which lead to longer amorphous marks (higher l), may present higher threshold voltages.

Again referring to FIG. 14, when programming the phase change cell 1400, only the central phase change standard material 102 will undergo a phase change, and therefore the amorphous length as well as the threshold voltage can be controlled at the same time that the length of the cell 1400 can be increased in order to improve the thermal isolation of the cell 1400. Therefore, power reduction may be achieved with no extra costs in terms of threshold voltages. Both edges 1402 of the line have been modified (for instance implanted or doped) to break the continuity of the standard phase change material 102. A programming pulse will produce a thermal profile 1428 as shown in FIG. 15, where only the phase change standard material will undergo phase transition. Then, no valid crystalline/amorphous interface will be formed since now the edges present an interface between amorphous phase change material 102 and the altered material 1402, which presents different properties from the standard material. So, crystallization of the area within the barriers will be driven by nucleation. A retarded crystallization is achieved, leading to a larger data retention time.

Programming power is highly affected by the heat confinement in the middle 102 of the phase change line 1402, 102, 1402. Hottest spots in phase change lines 1402, 102, 1402 occur close to the center 102 (however in many cases not exactly in the middle). Heat dissipation takes place mainly across the electrodes 106, 107, this makes long lines highly desirable since they keep the hot spot far from the electrodes 106, 107. However, long lines produce longer amorphous spots. Those longer spots require higher threshold voltages for reset switching. In order to avoid higher threshold voltages, amorphous spots need to be controlled. Since the switchable standard phase change material 102 can be reduced to the central region 102 of the cell according to an exemplary embodiment, only this area will become amorphous after a reset pulse, therefore, by adjusting the length of the switchable region 102, threshold voltage may be kept on specifications.

The altered phase change material 1402 may be made of any material, conductor, semiconductor or insulator. A conductor type material may be preferred since it does not affect the electrical continuity of the cell. Poor thermal conductivity may be desirable to enhance the heat confinement in the centre 102 of the line. The use of a semiconductor material can be advantageous in view of its good electrical conduction and bad thermal conduction (as for instance another kind of phase change material with a very high retention, or from the nucleation type). An insulator material may have a similar effect as the semiconductor. In conclusion, conductor, semiconductor or insulator materials can be used as altered phase change material 1402.

In an embodiment, implantation techniques may be used to form the altered phase change material 1402 from standard phase change material, or to form standard phase change material 102 from altered phase change material. Hence, a phase change line can be selectively implanted so the edges are altered to provide them with the desired properties.

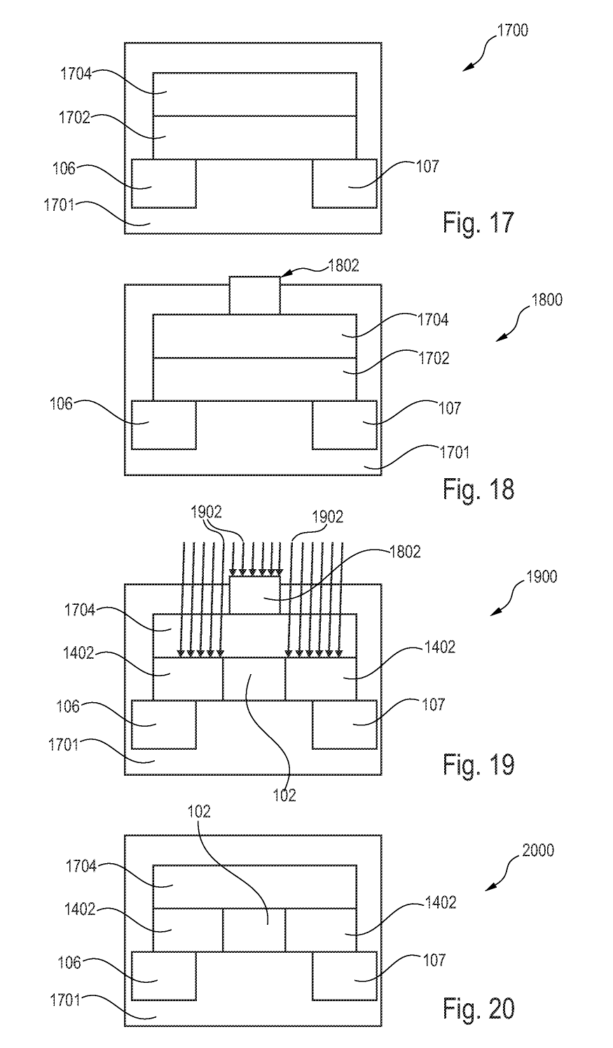

In the following, referring to FIG. 17 to FIG. 20, a method of manufacturing an electronic component according to an exemplary embodiment will be explained. Hence, FIG. 17 to FIG. 20 show, in lateral view, a summary of a process for implementation of a possible embodiment using implantation. This embodiment is based on a horizontal phase line cell.

As can be taken from a layer sequence 1700 as shown in FIG. 17, a first electrode 106 and a second electrode 107 are formed and are embedded in a dielectric structure 1701. A crystalline phase change line 1702 is formed in contact with both electrodes 106, 107. Subsequently, a hard mask 1704 is deposited on top of the crystalline phase change material 1702.

In order to obtain a layer sequence 1800 as shown in FIG. 18, an extra mask 1802 is deposited and patterned on top of the hard mask 1704 for shading in a top view exclusively a central portion of the crystalline phase change material 1702.

In order to obtain a layer sequence 1900 as shown in FIG. 19, the layer sequence 1800 is made subject of an implantation procedure, as indicated by reference numeral 1902. As a result of this implantation, the former crystalline phase change material 1702 is only maintained as a convertible structure 102 in the centre of the line (see reference numeral 102), whereas the edge portions with the former crystalline phase change line 1702 are converted into altered phase change material 1402, 1402.

After removal of the extra mask 1802, an electronic component 2000 according to an exemplary embodiment of the invention is obtained, as shown in FIG. 20.

An alternative manufacturing procedure will be explained in the following referring to FIG. 21 to FIG. 24. FIG. 21 to FIG. 24 show, in lateral view, a summary of another alternative process for implementation of a possible embodiment using implantation. This embodiment is based on a horizontal phase change line cell as well, although a vertical architecture is possible as well.

In order to obtain a layer sequence 2100 as shown in FIG. 21, the same procedure is performed as to obtain the layer sequence 1700 shown in FIG. 17 with the exception that as an alternative to the crystalline phase change material layer 1702, an altered phase change material layer 2102 is formed.

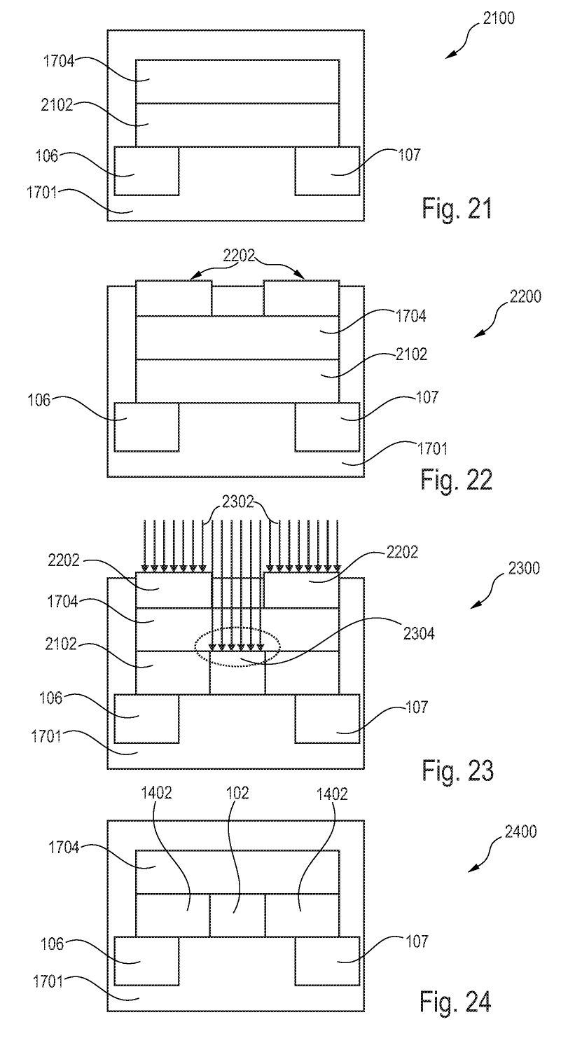

In order to obtain a layer sequence 2200 as shown in FIG. 22, an extra mask 2202 is formed which covers, in a view from above, only the edge portions of the line 2102.

In order to obtain a layer sequence 2300 as shown in FIG. 23, the layer sequence 2202 is made subject of an implantation process (compare reference numeral 2302). This results, in an area 2304, in a chemical modification of selectively a central part of the altered phase change material structure 2102.

In order to obtain an electronic component 2400 as shown in FIG. 24, the layer sequence 2300 is made subject of an annealing procedure and is subsequently treated so that the extra mask 2202 is removed. The consequence is a phase change material section 102 arranged between two remaining altered phase change material structures 1402.

Finally, it should be noted that the above-mentioned embodiments illustrate rather than limit the invention, and that those skilled in the art will be capable of designing many alternative embodiments without departing from the scope of the invention as defined by the appended claims. In the claims, any reference signs placed in parentheses shall not be construed as limiting the claims. The word “comprising” and “comprises”, and the like, does not exclude the presence of elements or steps other than those listed in any claim or the specification as a whole. The singular reference of an element does not exclude the plural reference of such elements and vice-versa. In a device claim enumerating several means, several of these means may be embodied by one and the same item of software or hardware. The mere fact that certain measures are recited in mutually different dependent claims does not indicate that a combination of these measures cannot be used to advantage.

1. An electronic component, the electronic component comprising
a first electrode;
a second electrode;
a convertible structure electrically coupled between the first electrode and the second electrode, being convertible between at least two states by heating and having different electrical properties in different ones of the at least two states;
a retention enhancement structure arranged between the first electrode and the second electrode, connected to the convertible structure and configured for suppressing conversion between different ones of the at least two states in the absence of heating.

2. The electronic component according to claim 1, wherein the retention enhancement structure comprises a barrier within the convertible structure configured for suppressing conversion between different ones of the at least two states in the absence of heating.

3. The electronic component according to claim 2, wherein the barrier is configured as a crystallization barrier for suppressing crystallization of the convertible structure.

4. The electronic component according to claim 1, wherein the retention enhancement structure comprises at least one of the group consisting of an electrically conductive material, an electrically isolating material, and a semiconductive material.

5. The electronic component according to claim 2, wherein the convertible structure is shaped as a line and the barrier comprises at least one layer traversing the line.

6. The electronic component according to claim 2, wherein the convertible structure is shaped as a line and the barrier comprises two layers traversing the line and delimiting an island-shaped sub-portion of the convertible structure.

7. The electronic component according to claim 2, wherein the barrier is configured for delimiting a sub-portion of the convertible structure;
wherein the electronic component comprises a control unit adapted for applying an electric signal to the convertible structure to selectively convert the entire delimited sub-portion of the convertible structure into one of the at least two states.

8. The electronic component according to claim 1, wherein one of the retention enhancement structure and the convertible structure comprises a material section being modified as compared to the other one of the retention enhancement structure and the convertible structure for suppressing conversion between different ones of the at least two states in the absence of heating.

9. The electronic component according to claim 8, wherein the material section comprises one of the group consisting of chemically modified material, doped material, material being modified by implantation, and material having a modified lattice constant.

10. The electronic component according to claim 8, wherein the retention enhancement structure is embedded between at least one of the first electrode and the second electrode on the one hand and the convertible structure on the other hand.

11. The electronic component according to claim 8, wherein the convertible structure and the retention enhancement structure form a line, wherein the retention enhancement structure forms two end sections of the line each of which being sandwiched between one of the first electrode and the second electrode on the one hand and the centrally arranged convertible structure on the other hand.

12. The electronic component according to claim 8, wherein a thermal conductivity of the convertible structure is lower than a thermal conductivity of the retention enhancement structure.

13. The electronic component according to claim 1, wherein the retention enhancement structure and the convertible structure are arranged relative to one another so that the electronic component is free of an interface between crystalline and amorphous material of the convertible structure in the absence of a programming electric signal.

14. The electronic component according to claim 1, adapted as one of the group consisting of a horizontal cell, a vertical cell, and an Ovonic cell.

15. The electronic component according to claim 1, wherein the convertible structure is a thermo-dependent structure, particularly a phase change structure that is convertible between at least two phase states.

16. The electronic component according to claim 1, wherein the convertible structure is a phase change structure of the fast growth type.

17. The electronic component according to claim 1, wherein the convertible structure is electrically conductive in at least one in the at least two states.

18. The electronic component according to claim 1, comprising an electric sensing circuit adapted for sensing the different electrical properties of the convertible structure in different ones of the at least two states.

19. The electronic component according to claim 1, wherein the convertible structure is adapted such that a value of the electrical conductivity differs between the at least two states.

20. The electronic component according to claim 1, wherein the convertible structure is adapted such that one of the at least two states relates to a crystalline phase of the convertible structure.

21. The electronic component according to claim 1, comprising a switch, particularly one of the group consisting of a transistor, a field effect transistor, a bipolar transistor, a FinFet, and a diode, electrically coupled to the convertible structure.

22. The electronic component according to claim 1, adapted as one of the group consisting of a memory device, a memory array, an actuator, a micro-electromechanical structure, a controller, and a switch.

23. The electronic component according to claim 1, wherein the retention enhancement structure is adapted to separate the convertible structure into at least two separate islands.

24. A method of manufacturing an electronic component, the method comprising
electrically coupling a convertible structure between a first electrode and a second electrode, the convertible structure being convertible between at least two states by heating and having different electrical properties in different ones of the at least two states;
forming a retention enhancement structure between the first electrode and the second electrode, connected to the convertible structure and configured for suppressing conversion between different ones of the at least two states in the absence of heating.

25. The method according to claim 24, wherein the forming comprises forming a barrier as the retention enhancement structure within the convertible structure configured for suppressing conversion between different ones of the at least two states in the absence of heating.

26. The method according to claim 24, wherein the forming comprises converting a material section of the convertible structure into the retention enhancement structure for suppressing conversion between different ones of the at least two states in the absence of heating.

27. The method according to claim 24, wherein the convertible structure is formed by converting a material section of the retention enhancement structure for suppressing conversion between different ones of the at least two states in the absence of heating into the convertible structure.

28. The method according to claim 24, wherein after forming one of the retention enhancement structure and the convertible structure, a material section thereof is converted into the other one of the retention enhancement structure and the convertible structure by implanting a substance using a mask.
